(19) United States
(12) Patent Application Publication
(10) Pub. No.: US 2001/0040817 A1
(43) Pub. Date: Nov. 15, 2001

(54) SRAM having a reduced chip area

(76) Inventor: Mitsuhiro Azuma, Kanagawa (JP)

Correspondence Address: MCGINN & GIBB, PLLC, 8321 OLD COURTHOUSE ROAD, SUITE 200, VIENNA, VA, 22182-3817, US

(21) Appl. No.: 09/734,029

(22) Filed: Dec. 12, 2000

(30) Foreign Application Priority Data
Dec. 13, 1999 (JP) 11-352838

(51) Int. Cl. G11C 11/00

(52) U.S. Cl. 365/154

(57) ABSTRACT

A SRAM has a precharge circuit disposed for each column of memory cells, the precharge circuit including a first precharge section disposed between two of memory cells and a pair of second precharge sections each disposed at the periphery of the column. The first precharge section has a configuration similar to the configuration of each memory cell, whereas the second precharge section has a different configuration. A dummy cell is disposed between the second precharge section and a memory cell for prevention of micro-loading effect.

### BACKGROUND OF THE INVENTION

(a) Field of the Invention

The present invention relates to a SRAM (static random access memory) having a reduced chip area and, more particularly, to a technique for reducing the area for a dummy cell while preventing a micro-loading effect etc.

(b) Description of the Related Art

In a SRAM, the load of the precharge circuit has become more and more heavy, due to the increase in the number of memory cells along with the increase of the storage capacity. Accordingly, in a SRAM having a large storage capacity, a pair of precharge sections are separately disposed as a combined precharge circuit at both the peripheries of each of the columns of the memory cell array, to thereby improve the precharge speed by the precharge circuit.

It is known in fabrication of general semiconductor devices that a difference in the etching rate appears between the regions having different pattern configurations. The difference in the etching rate depends on the difference of the ratio of the patterned area to the total area in each region. In the SRAM, such a difference arises because specific control circuits, such as the precharge circuit, having a configuration different from the configuration of the memory cells is disposed in the chip area wherein a large number of memory cells are arranged as repetitive patterns.

A micro-loading effect is also known between the regions having different patterns during the exposure process. The micro-loading effect is such that the difference in the design circuit pattern between regions generates a deformation of the circuit pattern during the exposure process. The micro-loading effect causes a change in the capacitance in the memory cell or the configuration of the memory cell in a semiconductor memory device.

A technique for preventing the generation of the micro-loading effect or the deformation caused by the etching process (simply referred to as micro-loading effect etc. in this text) uses a dummy cell disposed in the peripheral area of the SRAM, i.e., between the column of the memory cell and the precharge sections.

Patent Publication JP-A-11-54725 describes a technique for prevention of the micro-loading effect in a DRAM without using the dummy cell. FIGS. 1A and 1B are a circuit diagram and a top plan view, respectively, of the memory cell array and a precharge circuit in a conventional DRAM, described in the publication. The memory cell array 102 has a plurality of memory cells 31 arranged in a matrix, although only a group of four memory cells 31 are depicted for exemplification. Each memory cell 31 includes a single cell transistor 32 and a single cell capacitor 33. The precharge circuit 101 is disposed at the periphery of the memory cell array 102 and has functions for precharging a bit line 34 up to a specified potential level and for equalizing the potentials of a pair of bit lines 34 disposed adjacent to each other.

The precharge circuit 101 has precharge transistors 35 each having a configuration similar to that of the cell transistor 32 in the memory cell array 102, and thus has a pattern similar to the pattern of two memory cells 31 in the memory cell array 102 except for the configuration of a stacked polysilicon layer 36, as understood from FIG. 1B. For prevention of variations of the capacitance of the cell capacitor 33 caused by the micro-loading effect, an area for a dummy word line is disposed adjacent to the memory cell array 102. The precharge circuit 101 is disposed on the bit lines 34 similarly to the memory cells 31.

It is recited in the publication that the polysilicon layer 36 in the precharge circuit 101, which is used in the memory cell array 102 for implementing cell capacitors 33, is not used for the capacitor, and thus the deformation of the polysilicon layer 36 generated in the precharge circuit 102 due to the micro-loading effect does not cause a problem of change in the capacitance.

### SUMMARY OF THE INVENTION

It is an object of the present invention to provide a SRAM having a reduced chip area without using a dummy cell between a memory cell and a specific section of the precharge circuit while reducing the micro-loading effect etc.

The present invention provides a SRAM including a plurality of memory cells arranged in row and column directions, a plurality of word lines each disposed for a corresponding row of the memory cells, a plurality of digit line pairs each disposed for a corresponding column of the memory cells, and a precharge circuit disposed for each of said digit line pairs and including a first precharge section disposed between two of said memory cells in a corresponding column, the first precharge section having first transistors in number same as a number of cell transistors in each of the memory cells.

In accordance with the SRAM of the present invention, the precharge circuit includes the first precharge section disposed within the column of memory cells between two of the memory cells, and the number of transistors in the first precharge section is same as the number of cell transistors in the memory cell, whereby the precharge section does not disturb the iterative occurrence of the similar patterns in the column. This configuration allows reduction of micro-loading effect during the fabrication of the SRAM while assuring the precharge speed, and affords an accurate pattern configuration of the precharge section and the memory cells based on the design of the SRAM.

The above and other objects, features and advantages of the present invention will be more apparent, from the following description, referring to the accompanying drawings.

### BRIEF DESCRIPTION OF THE DRAWINGS

FIGS. 1A and 1B are a circuit diagram and a top plan view, respectively, of a portion of the conventional DRAM described in a publication.

FIG. 2 is a circuit diagram of a column of a memory cell array in a SRAM according to a first embodiment of the present invention, showing schematic arrangement thereof.

FIG. 3 is a circuit diagram of the memory cell and the dummy cell shown in FIG. 2.

FIG. 4 is a circuit diagram of the first precharge section shown in FIG. 2.

FIG. 5 is a circuit diagram of the second precharge section shown in FIG. 2

FIG. 6 is a timing chart of potentials of the digit lines and the precharge control line in the SRAM of FIG. 2.

FIG. 7 is a circuit diagram of a column of a memory cell array in a SRAM according to a second embodiment of the present invention, showing schematic arrangement thereof.

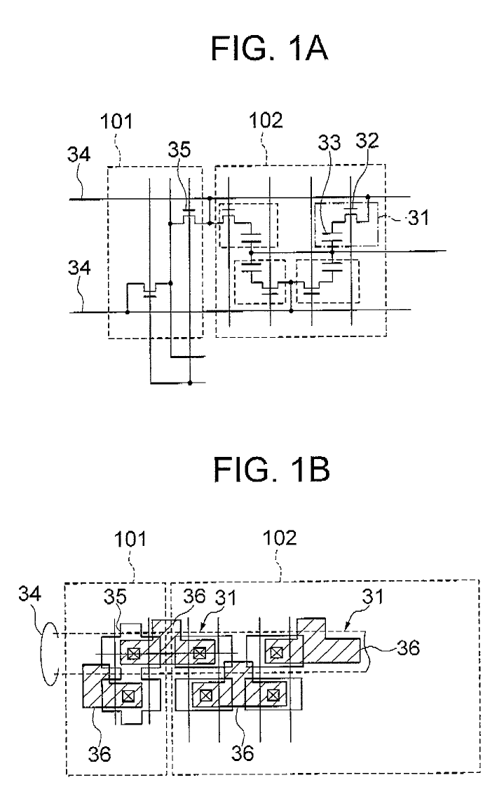

### PREFERRED EMBODIMENTS OF THE INVENTION

Now, the present invention is more specifically described with reference to accompanying drawings, wherein similar constituent elements are designated by similar reference numerals.

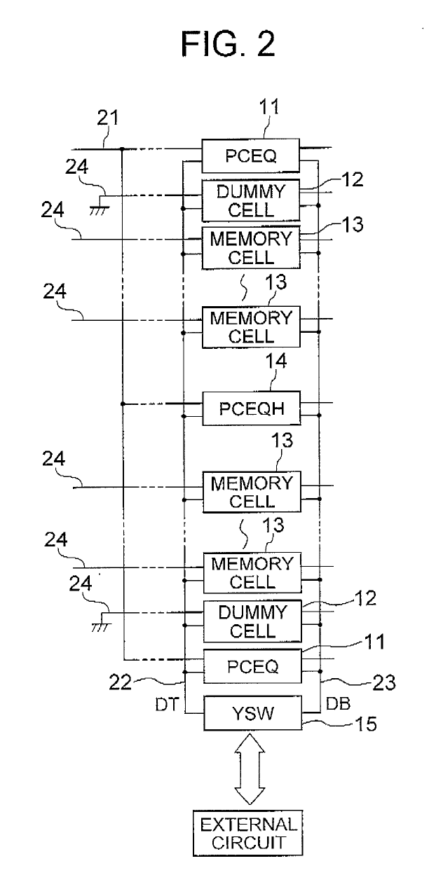

Referring to FIG. 2, a SRAM according to a first embodiment of the present invention includes a memory cell array including a plurality of memory cells 13 arranged in a matrix along row and column directions, wherein a column of the memory cell array is depicted in the drawing as a circuit diagram while showing the schematic arrangement thereof. The memory cell array includes a plurality of word lines 24 each extending in the row direction for the memory cells 13 arranged in a row for activating the corresponding memory cells 13.

The memory cell array also includes, in each column, a pair of digit lines (DT, DB) 22 and 23, to which each memory cell 13 is connected for transferring read/write data, a precharge circuit including at least one first precharge section (PCEQH) 14 and a pair of second precharge section (PCEQ) 14, a dummy cell 12 disposed between each of the second precharge sections 11 and one of the memory cells 13, and a sense amplifier (YSW) 15. If a plurality of the first precharge sections 14 are to be disposed, the first precharge sections 14 are arranged separately from one another with a constant pitch.

The second precharge sections 11 are disposed outside the dummy cells 12 disposed at the outer peripheries of the column of the memory cells 13. The first precharge section 14 is disposed in an area disposed between a pair of memory cells 13 without sandwiching therebetween a dummy cell 12. The sense amplifier 15 is disposed outside one of the second precharge sections 11 between the column and the external circuit 25.

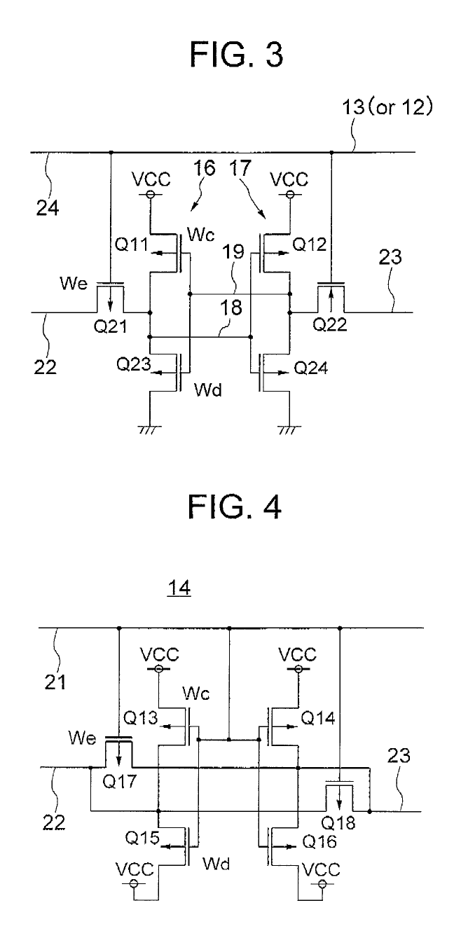

Referring to FIG. 3, the memory cell 13 (as well as the dummy cell 12) includes a first and second CMOSFETs 16 and 17 each including pMOSFET Q11 or Q12 and nMOSFET Q23 or Q24 and connected between a power supply line VCC and the ground line. Each of the CMOSFETs 16 and 17 has an output node 18 or 19 connected to the gate line of the other of the CMOSFETs 16 and 17 and to a corresponding one of the digit lines 22 and 23 through a corresponding transfer nMOSFET Q21 or Q22. The gates of nMOSFETs Q21 and Q22 are connected to a corresponding word line 24, which is connected to a row decoder in case of the memory cell 13 or grounded in case of the dummy cell 12.

All of the pMOSFETs Q11 and Q12 and the nMOSFETs Q21 to Q24 in the memory cell 13 have a gate length of “L”, whereas each of pMOSFETs Q11 and Q12, each of nMOSFETs Q21 and Q22 and each of nMOSFETs Q23 and Q24 have gate widths Wc, We and Wd, respectively.

Referring to FIG. 4, the first precharge section 14 includes six pMOSFETs Q13 to Q18 for precharging and equalizing the digit lines 22 and 23. Each of precharge pMOSFETs Q13 to Q16 has a source connected to the power supply line VCC, and a gate connected to a precharge control line 21. The drains of precharge pMOSFETs Q13 and Q15 are connected directly to digit line 22, whereas the drains of precharge pMOSFETs Q14 and Q16 are directly connected to digit line 23. Each of equalizing pMOSFETs Q17 and 018 has a gate connected to the precharge control line 21 and couples the digit lines 22 and 23 together at a low level of the precharge control line 21.

Each of pMOSFETs Q13 to Q18 has a gate length “L”, whereas each of pMOSFETs Q13 and Q14, each of pMOSFETs 15 and 16, and each of pMOSFETs Q17 and Q18 have gate widths Wc, Wd and We, respectively. The arrangement of pMOSFETs Q13 to 018 and patterned lines are similar to the arrangement of MOSFETs Q11, Q12 and Q21 to Q24 and the patterned lines in the memory cell 13. Thus, the pattern size and configuration of the first precharge section 14 of FIG. 4 are entirely similar to the pattern size and configuration of the memory cells 13 of FIG. 3.

The specified pattern size and configuration of the first precharge section 14 affords prevention of the micro-loading effect from being generated between the first precharge section 14 and the adjacent memory cells 13, whereby deformation of the pattern size can be substantially avoided.

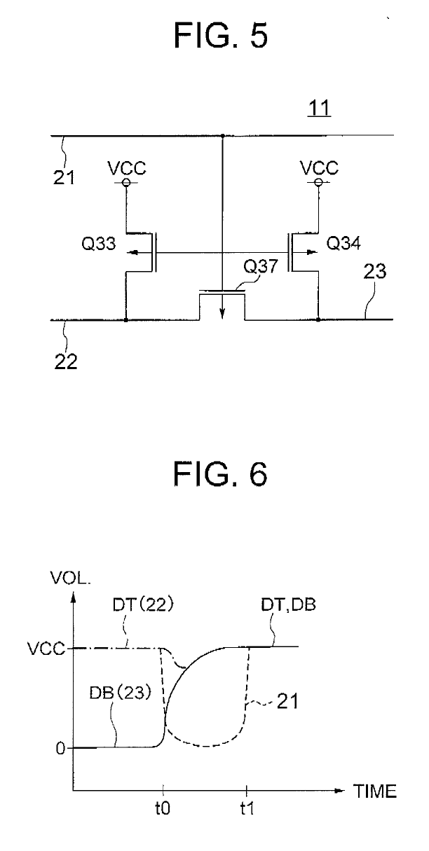

Referring to FIG. 5, the second precharge section 11 includes a pair of precharge pMOSFETs Q33 and Q34 each having a source connected to the power supply line VCC, a drain connected to a corresponding one of the digit lines 22 and 23, and a gate connected to the precharge control line 21, and an equalizing pMOSFET Q37 having a gate connected to the precharge control line 21 for coupling the digit liens 22 and 23 together at a low level of the precharge control line 21.

The pMOSFETs Q33, Q34 and Q37 have a gate length “L”, and gate widths Wa, Wa and Wb, respectively. That is, pMOSFETs Q33, Q34 and Q37 in the second precharge section 11 have configurations different from the configurations of the MOSFETs Q11, Q12 and Q21 to Q24 in the memory cell 13. The different configurations of the pMOSFETs Q33, Q34 and Q37 in the second precharge section 11 afford a wider variety of design choices compared to the first precharge section 14 in the precharge circuit to improve the operational characteristics of the precharge circuit.

Referring to FIG. 6, before a precharge period, or before time t0, digit line (DT) 22 and digit line (DB) 23 assume a high level and a low level, respectively, due to previous read data, whereas the precharge control line 21 assumes a high level, or inactive level. For precharge of the digit lines 22 and 23, the precharge control line 21 falls to an active low level, whereby all the pMOSFETs in the first and second precharge sections 14 and 11 are turned on for precharging and equalizing the digit lines 22 and 23. Thus, both the digit lines 22 and 23 assume a VCC level before the end of the precharge period. At the end of the precharge period, or at time t1, the precharge control line 21 rises to a high level, or inactive level, whereby all the pMOSFETs in the first and second precharge sections 14 and 11 are turned off Thus, both the digit lines 22 and 23 are ready to receive next read data or write data.

In the above embodiment, since a dummy cell 12 is not necessary between the memory cell 13 and the first precharge section 14 due to the specific configuration of the first precharge section 14 which is similar to that of the memory cell 13, the chip area cam be reduced. In addition, the precharge operation can be completed more quickly because of the reduced parasitic capacitance of the digit lines 22 and 23 due to the reduced number of dummy cells 12.

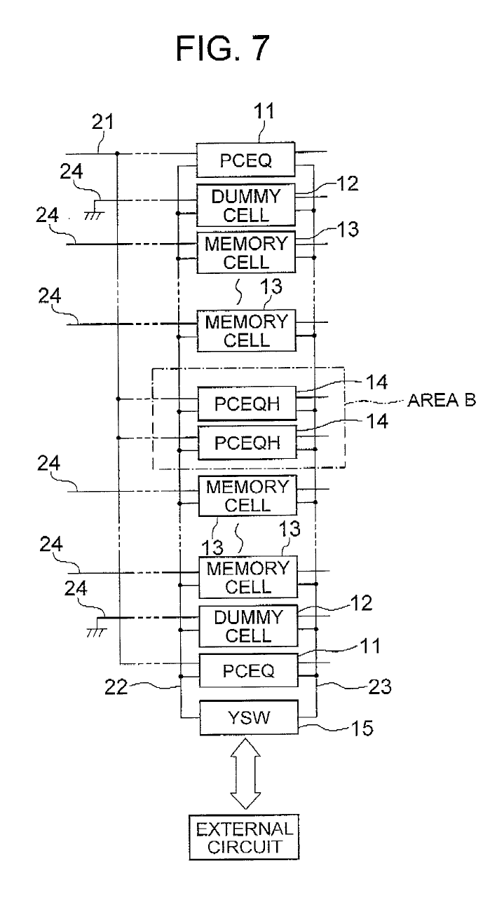

Referring to FIG. 7, a SRAM according to a second embodiment of the present invention is similar to the first embodiment except for a plurality of first precharge sections 14 disposed adjacent to one another. Each of the first precharge sections 14 includes six pMOSFETs having a transistor size equal to the transistor size of the memory cell 13, and has a pattern configuration similar to the pattern configuration of one of the memory cells 13.

The plurality of first precharge sections 14 afford a higher driving capability for precharging and equalizing the digit lines 22 and 23. This configuration is especially effective if the memory cell 13 includes cell transistors having a smaller size for a higher integration. The higher driving capability of the first precharge sections 14 accelerates the precharge of the digit lines 22 and 23 whereby the SRAM has a higher operational speed.

Since the above embodiments are described only for examples, the present invention is not limited to the above embodiments and various modifications or alterations can be easily made therefrom by those skilled in the art without departing from the scope of the present invention.

What is claimed is:

1. A static random access memory (SRAM) comprising a plurality of memory cells arranged in row and column directions, a plurality of word lines each disposed for a corresponding row of said memory cells, a plurality of digit line pairs each disposed for a corresponding column of said memory cells, and a precharge circuit disposed for each of said digit line pairs and including a first precharge section disposed between two of said memory cells in a corresponding column, said first precharge section having first transistors in number same as a number of cell transistors in each of said memory cells.

2. The SRAM as defined in claim 1, wherein each of said first transistors has a configuration similar to a configuration of a corresponding one of said cell transistors.

3. The SRAM as defined in claim 2, wherein said first transistors are arranged similarly to an arrangement of said cell transistors.

4. The SRAM as defined in claim 1, wherein said precharge circuit comprises a plurality of said first precharge sections each disposed between corresponding two of said memory cells.

5. The SRAM as defined in claim 1, wherein said precharge circuit comprises a plurality of said first precharge sections disposed in a block.

6. The SRAM as defined in claim 1, wherein said precharge circuit comprises a pair of second precharge sections each disposed at a periphery of said corresponding column of said memory cells.

7. The SRAM as defined in claim 6, wherein a dummy cell is disposed between each of said second precharge sections and one of said memory cells.

8. The SRAM as defined in claim 7, wherein each of said second precharge sections has second transistors in number different from the number of cell transistors in each of said memory cells.
